(19) United States
(12) Patent Application Publication
(10) Pub. No.: US 2013/0068521 A1
(43) Pub. Date: Mar. 21, 2013

(54) ELECTROMAGNETIC SHIELDING METHOD USING GRAPHENE AND ELECTROMAGNETIC SHIEDLING MATERIAL

(71) Applicants: Byung Hee Hong, Seoul (KR); Jea-Boong Choi, Yongin-si (KR); Young Jin Kim, Seoul (KR); Hyeongkeun Kim, Hwaseong-si (KR); Sukang Bae, Suwon-si (KR); Junmo Kang, Suwon-si (KR)

(72) Inventors: Byung Hee Hong, Seoul (KR); Jea-Boong Choi, Yongin-si (KR); Young Jin Kim, Seoul (KR); Hyeongkeun Kim, Hwaseong-si (KR); Sukang Bae, Suwon-si (KR); Junmo Kang, Suwon-si (KR)

(73) Assignee: SUNGKYUNKWAN UNIVERSITY FOUNDATION FOR CORPORATE COLLABORATION, Suwon-si (KR)

(21) Appl. No.: 13/582,944

(22) PCT Filed: Mar. 4, 2011
(86) PCT No.: PCT/KR2011/001491

§ 371 Date: Nov. 7, 2012

(30) Foreign Application Priority Data
Mar. 5, 2010 (KR) 10-2010-0020069

(51) Int. Cl. H05K 9/00; B32B 37/16; C23C 16/26

(52) U.S. Cl. CPC H05K 9/0084; C23C 16/26; B32B 37/16; B82Y 30/00
USPC 174/388; 427/122; 156/60; 977/734

(57) ABSTRACT

The present application relates to a method for shielding electromagnetic waves by using graphene inside or outside an electromagnetic wave generating source and/or by using graphene formed on a substrate, and an electromagnetic shielding material including the graphene.

### TECHNICAL FIELD

The present disclosure relates to a method for shielding electromagnetic waves by using graphene, and an electromagnetic wave shielding material using graphene.

### BACKGROUND ART

Electromagnetic waves are electromagnetic energy generated from use of electricity and have broad frequency domains. Depending upon frequencies, electromagnetic waves are classified into home power frequency (60 Hz), extremely low frequency (0 Hz to 1000 Hz), low frequency (1 kHz to 500 kHz), communication frequency (500 kHz to 300 kHz), and microwave (300 MHz to 300 GHz: G-1 billion). Frequencies become high in order of an infrared ray, a visible ray, an ultraviolet ray, an X-ray, and a gamma ray.

In recent, the rapid propagation of digital devices such as PCs and mobile phones has caused a flood of electromagnetic waves even at workplaces or homes. Damages by electromagnetic waves have occurred in various forms from malfunction of a computer and a burning accidence in a plant to an adverse effect on a human body. Thus, the technology of shielding electromagnetic waves in various electric and electronic products is arising as a core technical field of the electronics industry.

The technology of shielding electromagnetic waves may be divided into a method that protects external equipment by shielding the periphery of an electromagnetic wave generating source, and a method that stores equipment in the inside of a shielding material to protect the equipment from an external electromagnetic wave generating source. In this regard, recently, researches on shielding materials for shielding electromagnetic waves have been spotlighted. However, there are still many problems with regard to performance, applicability, costs, and others of the shielding materials.

### DISCLOSURE OF THE INVENTION

### Problems to Be Solved by the Invention

The inventors of the present application wish to provide a method for shielding electromagnetic waves by using graphene that can be prepared in a large scale by a chemical vapor deposition method, and an electromagnetic wave shielding material including the graphene.

However, the problems sought to be solved by the present disclosure are not limited to the above-described problems. Other problems, which are sought to be solved by the present disclosure but are not described herein, can be clearly understood by those skilled in the art from the descriptions below.

### Means for Solving the Problems

In order to solve the above-described problems, a method for shielding electromagnetic waves by using graphene in accordance with one aspect of the present disclosure includes forming graphene outside or inside an electromagnetic wave generating source to shield electromagnetic waves by the graphene. For the electromagnetic wave generating source, any device or product that generates electromagnetic waves can be used without limitation. For example, the electromagnetic wave generating source may include, but not limited to, various electronic/electric devices and components such as a TV, a radio, a computer, medical appliances, office machines, a communication device, and components thereof.

A method for shielding electromagnetic waves by using graphene in accordance with another aspect of the present disclosure includes attaching or wrapping a substrate, on which graphene is formed, to or around the outside or the inside of the electromagnetic wave generating source to shield electromagnetic waves by the graphene.

In an embodiment of the present disclosure, the graphene may be formed, but not limited to, outside or inside the electromagnetic wave generating source through a chemical vapor deposition method. In an illustrative embodiment of the present disclosure, the graphene may include, but not limited to, at least monolayer graphene.

In another embodiment of the present disclosure, the graphene may be formed by transferring the graphene formed on a substrate through the chemical vapor deposition method to the outside or the inside of the electromagnetic wave generating source. However, the present disclosure is not limited thereto. For example, the substrate may be, but not limited to, a flexible substrate or a flexible and transparent substrate.

In another embodiment of the present disclosure, the substrate may include, but not limited to, metal or polymer.

In another embodiment of the present disclosure, the graphene may be formed by transferring the graphene formed on the substrate through the chemical vapor deposition method to the outside or the inside of the electromagnetic generating source. However, the present disclosure is not limited thereto.

In another embodiment of the present disclosure, the graphene may be doped, but is not limited thereto.

In another embodiment of the present disclosure, sheet resistance of the graphene may be, but not limited to, about 60 Ω/sq or less.

In another embodiment of the present disclosure, the substrate may be in the form of a foil, a wire, a plate, a tube, or a net. However, the present disclosure is not limited thereto.

An electromagnetic wave shielding material in accordance with another aspect of the present disclosure is an electromagnetic wave shielding material including a substrate and graphene formed on a surface of the substrate. The graphene is formed by the chemical vapor deposition method and includes graphene with sheet resistance of about 60 Ω/sq or less. In an embodiment of the present disclosure, the graphene may include, but not limited to, at least monolayer graphene.

In another embodiment of the present disclosure, the graphene may be chemically doped. However, the present disclosure is not limited thereto.

In another embodiment of the present disclosure, the substrate may be, but not limited to, in the form of a foil, a wire, a plate, a tube, or a net.

In another embodiment of the present disclosure, the substrate may be, but not limited to, a flexible substrate or a flexible and transparent substrate.

In another embodiment of the present disclosure, the substrate may include, but not limited to, metal and polymer.

### Effect of the Invention

The present disclosure can effectively shield electromagnetic waves generated from various electromagnetic wave generating sources by using graphene uniformly prepared in a large scale and uniformly. More specifically, the present disclosure can shield electromagnetic waves in a broad frequency band of from about 2 GHz to about 18 GHz by using graphene, and furthermore, various substrates coated with graphene. Further, the present disclosure can improve electromagnetic wave shielding efficiency through chemical, physical, and structural improvement of graphene.

### BRIEF DESCRIPTION OF THE DRAWINGS

FIG. 1 is a block diagram showing a process for forming graphene on a substrate and its associated apparatus in accordance with an embodiment of the present disclosure;

FIG. 2 is a graph showing sheet resistance and an electric characteristic of graphene in accordance with an example of the present disclosure;

FIG. 3 is a graph obtained from measurement of an electromagnetic wave shielding effect of graphene doped by various dopants in an example of the present disclosure;

FIG. 4 is a graph obtained from measurement of an electromagnetic wave shielding effect of a Cu foil and graphene formed on a Cu foil in an example of the present disclosure;

FIG. 5 is a graph obtained from measurement of an electromagnetic wave shielding effect of a Cu mesh and graphene formed on a Cu mesh in an example of the present disclosure;

FIG. 6 is a Raman spectroscope analysis result of graphene formed on a metal substrate in accordance with an example of the present disclosure;

FIG. 7 is a graph showing an electric characteristic depending on whether graphene is formed on a metal substrate or not, in accordance with an example of the present disclosure;

FIG. 8 is a photograph obtained from observation of graphene formed on various substrates in an example of the present disclosure; and

FIG. 9 is a schematic view of an apparatus for measurement of a shielding effect in accordance with an embodiment of the present disclosure.

### BEST MODE FOR CARRYING OUT THE INVENTION

Hereinafter, illustrative embodiments and examples of the present disclosure will be described in detail with reference to the accompanying drawings so that inventive concept may be readily implemented by those skilled in the art.

However, it is to be noted that the present disclosure is not limited to the illustrative embodiments and the examples but can be realized in various other ways. In the drawings, certain parts not directly relevant to the description are omitted to enhance the clarity of the drawings, and like reference numerals denote like parts throughout the whole document.

Throughout the whole document, the term “comprises or includes” and/or “comprising or including” used in the document means that one or more other components, steps, operations, and/or the existence or addition of elements are not excluded in addition to the described components, steps, operations and/or elements.

The terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party.

Electromagnetic wave shielding means shielding electromagnetic interference (EMI) incident from the outside, and absorbs/reflects electromagnetic waves on a surface so as to prevent the electromagnetic waves from being transferred into the inside. The present disclosure effectively shields electromagnetic waves by using large scale graphene, rather than metal or conductive organic polymer, which has been conventionally used as an electromagnetic shielding material.

The method for shielding electromagnetic waves by using graphene in the present disclosure includes forming graphene outside or inside an electromagnetic wave generating source to shield electromagnetic waves by the graphene.

In order to form graphene outside or inside the electromagnetic wave generating source, various methods may be used. As various embodiments of the method for shielding electromagnetic waves in accordance with the present disclosure, electromagnetic waves may be shielded by forming graphene directly outside or inside the electromagnetic wave generating source, transferring graphene formed on a substrate to the outside or the inside of the electromagnetic wave generating source, or forming the substrate itself, on which the graphene is formed, outside or inside the electromagnetic wave generating source.

As the method for forming graphene, which is used as an electromagnetic wave shielding material, any method can be used without limitation if the method is generally used in the art of the present disclosure to grow graphene. For example, a chemical vapor deposition method may be used. However, the present disclosure is not limited thereto. The chemical vapor deposition method may include, but not limited to, rapid thermal chemical vapour deposition (RTCVD), inductively coupled plasma-chemical vapor deposition (ICPCVD), low pressure chemical vapor deposition (LPCVD), atmospheric pressure chemical vapor deposition (APCVD), metal organic chemical vapor deposition (MOCVD), and plasma-enhanced chemical vapor deposition (PECVD).

The process for growing graphene may be performed under an atomospheric pressure, a low pressure, or vacuum. For example, if the process is performed under the condition of an atomospheric pressure, helium (He) or the like may be used as a carrier gas to minimize damage to the graphene caused by collision with heavy argon (Ar) at a high temperature. Also, if the process is performed under the condition of an atomospheric pressure, a large scale graphene film can be produced through a simple process at low costs. If the process is performed under the condition of a low pressure or vacuum, hydrogen (H₂) may be used as an atmosphere gas, while increasing a temperature during the process, so that an oxidized surface of a metal catalyst is reduced, and high quality graphene can be synthesized.

The graphene formed by the above-described method may have a large scale with a horizontal and/or vertical length of from about 1 mm to about 1,000 m. The graphene may have a homogeneous structure with little deficits. The graphene formed by the above-described method may include monolayer or multilayer graphene. An electric characteristic of the graphene may vary depending on the thickness of the graphene. Accordingly, the electromagnetic wave shielding effect may vary. As an unlimited example, the thickness of the graphene may be adjusted in a range of from 1 layer to 100 layers.

The graphene may be formed on a substrate. In this case, as described above, electromagnetic waves may be shielded by transferring the graphene formed on the substrate to the outside or the inside of the electromagnetic wave generating source, or attaching or wrapping the substrate itself, on which the graphene is formed, to or around the outside or the inside of the electromagnetic wave generating source. A shape of the substrate is not limited. For example, the substrate may be in the form of a foil, a wire, a plate, a tube, or a net. The electromagnetic shielding effect may vary depending on the shape of the substrate.

Materials for the substrate are not specially limited. For example, materials for the substrate may include at least one metal or alloy selected from the group consisting of silicone, Ni, Co, Fe, Pt, Au, Al, Cr, Cu, Mg, Mn, Mo, Rh, Si, Ta, Ti, W, U, V, Zr, brass, bronze, white brass, stainless steel, Ge, and polymer. If the substrate is formed of metal, the metal substrate may function as a catalyst for the formation of the graphene.

However, the substrate does not need to be formed of metal. For example, silicon may be used for the substrate. For formation of a catalyst layer on the silicon substrate, a substrate, on which a silicon oxide layer is further formed through oxidization of the silicon substrate, may be used. The substrate may be a polymer substrate and include polymers such as polyimide (PI), polyethersulfon (PES), polyetheretherketone (PEEK), polyethyleneterephthalate (PET), or polycarbonate (PC). As a method for forming graphene on the polymer substrate, any of the aforementioned chemical vapor deposition methods can be used. More preferably, the plasma-enhanced chemical vapor deposition method may be used at a low temperature of from about 100° C. to about 600° C.

Here, in order to facilitate the growth of graphene on the substrate, a catalyst layer may be further formed. Any catalyst layer may be used, regardless of materials, thickness, and a shape thereof. For example, the catalyst layer may be at least one metal or alloy selected from the group consisting of Ni, Co, Fe, Pt, Au, Al, Cr, Cu, Mg, Mn, Mo, Rh, Si, Ta, Ti, W, U, V, Zr, brass, bronze, white brass, stainless steel, and Ge. The catalyst layer may be formed of the same or different material as or from the substrate. Thickness of the catalyst layer is not limited and may be a thin or thick film.

In an embodiment for forming graphene on the substrate, the graphene may be grown by winding a metal substrate of a thin film or foil form into a roll form, putting the matal substrate into a tube-shaped furnace, supplying a reaction gas containing a carbon source, and performing heat treatment at an atomospheric pressure. The heat processing is performed, for example, at a temperature of from about 300° C. to about 2,000° C., while vaporously supplying a carbon source such as carbon monoxide, carbon dioxide, methane, ethane, ethylene, ethanol, acetylene, propane, butane, butadiene, pentane, pentene, cyclopentadiene, hexane, cyclohexane, benzene, or toluene. As a result, carbon components existing in the carbon source are bonded to one another to form a hexagonal plate shape structure so that the graphene film is grown.

The graphene formed as described above may be transferred onto the substrate by various methods. For the transferring method, any transferring method can be used without limitation if the transferring method is generally used in the art of the present disclosure. For example, a dry process, a wet process, a spray process, or a roll-to-roll process may be used. More preferably, in order to transfer large scale graphene through a simple process at low costs, the roll-to-roll process may be used. However, the present disclosure is not limited thereto.

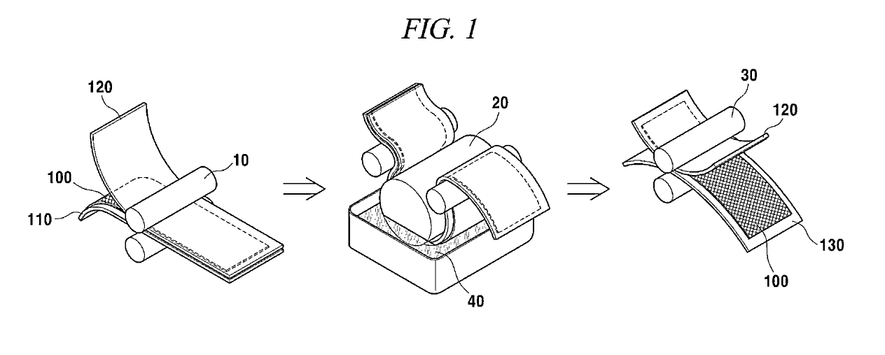

FIG. 1 is a block diagram showing a process for forming graphene on a substrate and an associated transferring apparatus in accordance with an embodiment of the present disclosure. The transferring process includes rolling a flexible substrate, on which graphene is formed, and a target substrate in contact with the graphene by using a transfer roller to transfer the graphene onto the target substrate. To be more specific, the transferring process may include three steps, which include: rolling graphene 100 formed on a graphene growth supporter 110 and a flexible substrate in contact with the graphene by using a first roller 10, which is an adhesion roller, to form a layered structure of graphene growth supporter-graphene-flexible substrate; immersing the layered structure into an etching solution 40 and passing the layered structure through the etching solution 40 by using a second roller 20 to etch the graphene growth supporter and transfer the graphene onto the flexible substrate 120; and rolling the flexible substrate, onto which the graphene is transferred, and a target substrate 130 in contact with the graphene by using a third roller 30, which is a transfer roller, to transfer the graphene onto the target substrate. Here, the graphene growth supporter 110 may include a metal catalyst for the graphene growth and an additional substrate, which is selectively formed on a bottom portion thereof. In an illustrative embodiment of the present disclosure, the metal catalyst for the graphene growth may include, but not limited to, a metal catalyst selected from the group consisting of Ni, Co, Fe, Pt, Au, Al, Cr, Cu, Mg, Mn, Rh, Si, Ta, Ti, W, U, V, and Zr.

An adhesive layer may be formed on the flexible substrate 120. For example, the adhesive layer may include, but not limited to, thermal release polymer, low density polyethylene, low molecular polymer, high molecular polymer, or ultraviolet or infrared ray curable polymer. Specifically, for the adhesive layer, PDMS, various types of poly urethane films, a water system adhesive, which is an environment-friendly adhesive, a water soluble adhesive, a vinyl acetate emulsion adhesive, a hot melt adhesive, a photo-curable (UV, visible light, electron beam, and UV/EB curable) adhesive, a NOA adhesive, and high heat resistance adhesives such as polybenizimidazole (PBI), polyimide (PI), silicone/imide, bismaleimide (BMI), and modified epoxy resin, and the like may be used. Various general adhesive tapes may also be used. As described above, large scale graphene may be transferred from the graphene growth supporter onto a flexible substrate through the roll-to-roll process. The process for transferring the graphene onto the target substrate may be more easily performed within short time at low costs. As the process for transferring the graphene onto the substrate, the roll-to-roll process has been described in detail. However, the present disclosure is not limited to the roll-to-roll process. The graphene may be transferred onto the substrate by various processes.

Once electromagnetic waves are incident onto a shielding material, the electromagnetic waves are absorbed, reflected, diffracted, or penetrate. In this case, the total sum of the shielding effects refers to shielding efficiency, which is represented by the following formula:

SE=SER+SEA+SEB (1.1)

Here, SER indicates decrease (dB) by reflection. SEA indicates decrease (dB) by absorption, and SEB indicates decrease (dB) by interior reflection of the shielding material. In the formula 1.1, if SEA is more than 10 dB, the SEB may be disregarded. SER (decrease by reflection) and SEA (decrease by absorption) are represented by the following formulas 1.2 and 1.3, respectively:

SER=50+10 log(ρF)−1 (1.2)

SEA=1.7t(F/ρ)1/2 (1.3)

Here, ρ refers to volume resistivity (W×cm); F refers to frequency (MHz); and t refers to thickness (cm) of the shielding material.

With reference to the formulas 1.2 and 1.3, it can be understood that the shielding efficiency increases as the thickness of the shielding material is large, and the volume resistivity is small.

In general, levels of the shielding effect follow the reference described hereinafter. There is little shielding effect in a range of from about 0 dB to about 10 dB. At least a certain degree of the shielding effect is found in a range of from about 10 dB to about 30 dB. An average degree of the shielding effect may be expected in a range of from about 30 dB to about 60 dB. In a range of about 60 dB to about 90 dB, at least an average degree of the shielding effect is achieved. In a range of about 90 dB or more, almost all electromagnetic waves can be shielded. An electromagnetic wave shielding material using metal is generally known to have a shielding effect of about 60 dB or more.

The shielding method using graphene in the present disclosure may adopt various methods to improve the shielding efficiency. More specifically, the shielding efficiency can be improved through chemical, physical, and structural improvement. For example, in order to improve the electromagnetic wave shielding efficiency by improving sheet resistance of the graphene, a method of changing the number of stacked layers of the graphene or doping the graphene may be used. However, the present disclosure is not limited thereto. If graphene formed on a substrate is used as a shielding material, the electromagnetic wave shielding efficiency may be improved depending on a shape of the substrate.

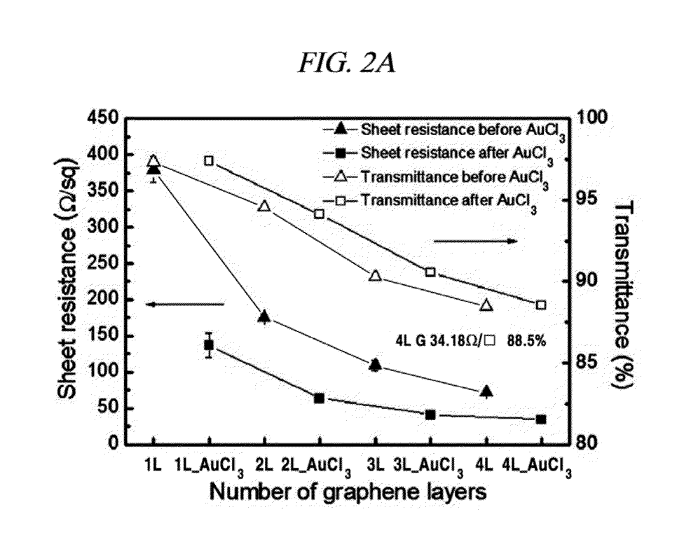

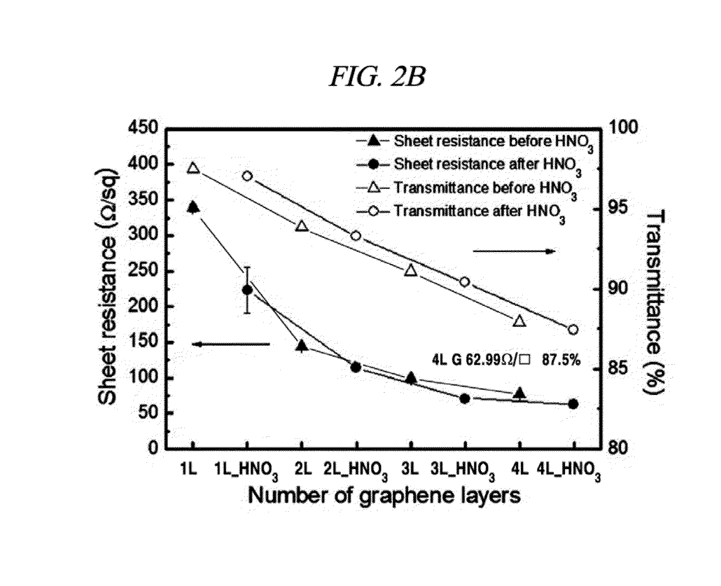

The electromagnetic wave shielding efficiency may be improved by changing the number of layers of the graphene. However, the present disclosure is not limited thereto. For example, multilayer graphene may be formed by repeating the aforementioned roll-to-roll transferring process. However, the present disclosure is not limited thereto. The multilayer graphene may remedy deficits of a monolayer graphene. More specifically, with reference to FIG. 2, it is understood that the sheet resistance of the graphene decreases as the number of layers of the graphene increases. With reference to FIG. 2a, in case of graphene doped with AuCl₃—CH₃NO₂ in accordance with an example of the present disclosure, the sheet resistance of the graphene decreases from about 140 Ω/sq to about 34 Ω/sq as first to fourth layers are stacked in order. Also, in case of graphene doped with NHO₃, the sheet resistance of the graphene decreases from about 235 Ω/sq to about 62 Ω/sq as first to fourth layers are stacked in order.

As another embodiment for improvement of the electromagnetic wave shielding efficiency, a method of doping the graphene by using a dopant may be used. However, the present disclosure is not limited thereto. For the method of doping the graphene, any doping method may be used without limitation if the method is generally used in the art of the present disclosure. As illustrated in FIG. 1, the graphene may be doped, but not limited to, by a roll-to-roll apparatus. If the graphene is doped by the roll-to-roll process, the whole processes for preparing, doping, and transferring the graphene can be performed by the simple and consecutive process, i.e., the roll-to-roll process.

The doping process may be performed by using a doping solution including dopant, or dopant steam. For example, in case of using the dopant steam, the dopant steam may be formed by a heating apparatus for vaporizing the doping solution in a vessel containing the doping solution.

The dopant may include, but not limited to, at least one selected from the group consisting of ionic liquid, ionic gas, an acidic compound, and an organic molecular system compound. The dopant may include, but not limited to, at least one selected from the group consisting of NO₂BF₄, NOBF₄, NO₂SbF₆, HCl, H₂PO₄, H₃CCOOH, H₂SO₄, HNO₃, PVDF, Nafion, AuCl₃, SOCl₂, Br₂, CH₃NO₂, dichlorodicyanoquinone, oxon, dimyristoylphosphatidylinositol, and trifluoromethanesulfonimide. An electric characteristic of the graphene such as the sheet resistance may be adjusted by changing dopant and/or doping time during the doping process.

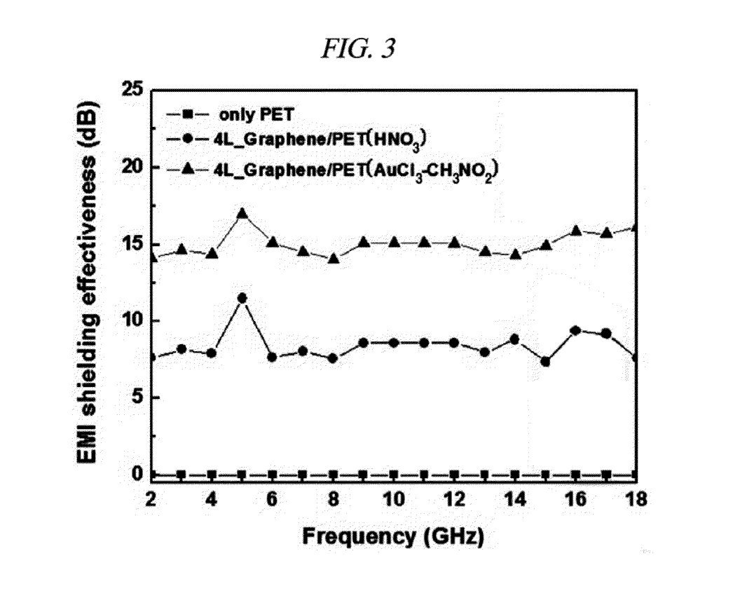

FIGS. 2 and 3 provide results exhibiting the electric characteristic and the shielding efficiency of graphene depending on various dopants in accordance with an example of the present disclosure. More specifically, in an example of the present disclosure, with reference to FIG. 2, the resistance of the graphene doped with AuCl₃—CH₃NO₂ decreased, compared to pristine graphene.

FIG. 3 shows shielding testing results for shielding materials prepared by doping tetralayer graphene with different dopants in accordance with an example of the present disclosure. More specifically, in an example of the present disclosure, a PET substrate, tetralayer graphene doped with HNO₃ on the PET substrate, and tetralayer graphene doped with AuCl₃—CH₃NO₂ on the PET substrate were used as shielding materials. The shielding efficiency was measured by increasing the frequency domain from about 2 GHz to about 18 GHz. In an example of the present disclosure, the shielding efficiency of the HNO₃ doped graphene shielding material with the sheet resistance of about 62 Ω/sq (refer to FIG. 2b) was improved by about 7.6%, compared to the PET shielding material. In case of the graphene shielding material doped with AuCl₃—CH₃NO₂ (sheet resistance of about 32 Ω/sq; refer to FIG. 2a), about 15% of the shielding improvement effect was achieved. With reference to the results in FIGS. 2 and 3, in an example of the present disclosure, the sheet resistance decreasing rate and the shielding rate of the graphene are in a linear proportional relation depending on the doping method and the number of layers of graphene.

As another embodiment for improvement of the electromagnetic wave shielding efficiency, if graphene formed on a substrate is used as a shielding material, the shielding efficiency may vary depending on a shape of the substrate.

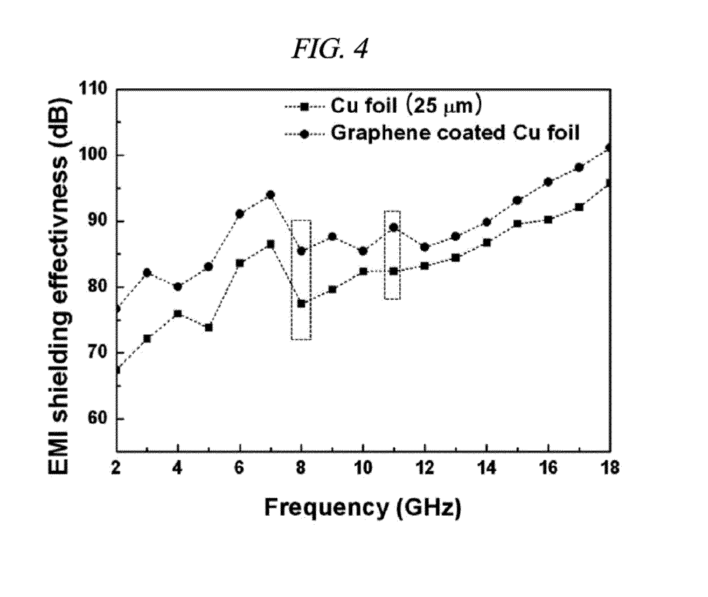

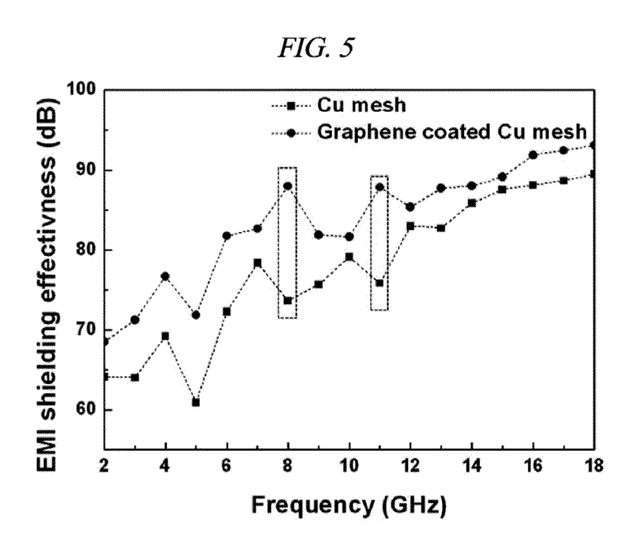

FIGS. 4 and 5 provide analysis results for the shielding efficiency of the graphene depending on a shape of a substrate in an example of the present disclosure. More specifically, in FIG. 4, graphene formed on a Cu foil was used as a shielding material. In FIG. 5, graphene formed on a Cu mesh was used as a shielding material. The graphenes formed on the Cu foil and the Cu mesh are the same. The shielding efficiency of the shielding materials was tested in the frequency domain of from about 2 GHz to about 18 GHz. With reference to FIG. 4, in an example of the present disclosure, the graphene shielding material formed on the Cu foil exhibited the biggest variation width at 8 GHz, compared to the shielding material only formed of the Cu foil. Based on the analysis results, the shielding efficiency was improved by about 10.62%. The shielding efficiency was improved by about 8.2% at 11 GHz in an example of the present disclosure. With reference to FIG. 5, in an example of the present disclosure, the graphene shielding material formed on the Cu mesh exhibited about 19% improvement of the shielding efficiency at 8 GHz, and about 17% improvement of the shielding efficiency at 11 GHz, compared to the shielding material only formed of the Cu mesh.

As described above, the method for shielding electromagnetic waves by using graphene in the present disclosure and the shielding material using the graphene are expected to be widely applied in various fields as novel materials capable of maximizing the electromagnetic wave shielding efficiency, in addition to effects such as device weight reduction, oxidization prevention, and surface roughness improvement.

Hereinafter, examples of the method for shielding electromagnetic waves by using graphene in the present disclosure and the shielding material using the graphene will be described in detail. However, the present disclosure is not limited to the examples.

### EXAMPLE 1

1. Growth of Large Scale Graphene on a Copper Foil

A ˜7.5 inch quartz tube was wrapped with a Cu foil (thickness: 25 μm; size: 210×297 mm²; Alfa Aesar Co.) to form a roll of the Cu foil. The quartz tube was inserted into a ˜8 inch quartz tube and fixed therein. Thereafter, the quartz tube was heated to 1,000° C. while flowing 10 sccm H₂ at 180 mTorr. After the temperature of the quartz tube reaches 1,000° C., annealing was performed for 30 minutes while maintaining the flow of H₂ and the pressure. Subsequently, a gas mixture (CH₄: H₂=30:10 sccm) containing a carbon source was supplied at 1.6 Torr for 15 minutes to grow graphene on the Cu foil. Thereafter, the graphene was cooled to a room temperature at a velocity of ˜10° C./s within short time while flowing H₂ under a pressure of 180 mTorr so that the graphene grown on the Cu foil was obtained.

2. Transferring Process of Graphene and a Roll-to-Roll Doping Process

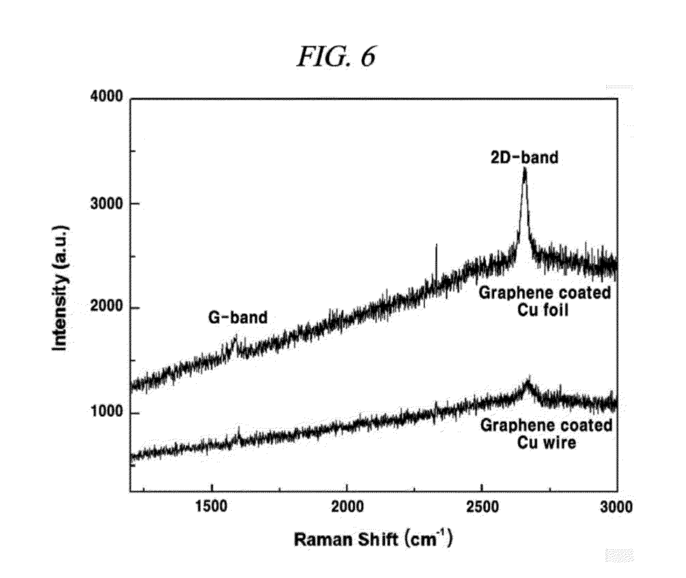

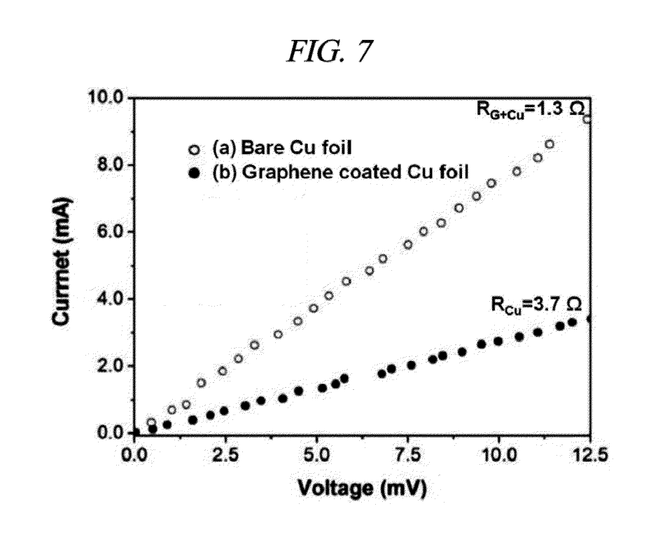

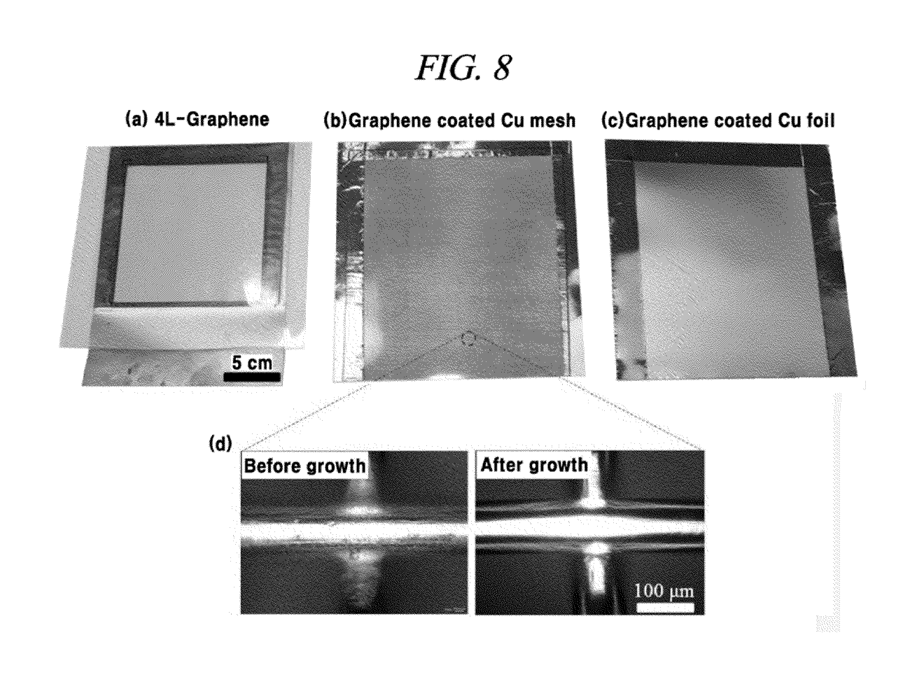

After a thermal release tape (Jin Sung Chemical Co. and Nitto Denko Co.) was contacted with the graphene formed on the Cu foil, the graphene was passed through an adhesion roller including two rollers under the condition that a low pressure of ˜2 MPa was applied, to adhere the graphene onto the thermal release tape. Next, the Cu foil/graphene/thermal release tape layered structure was immersed in a 0.5 M FeCl₃ or 0.15M (NH₄)₂S₂O₈ etching aqueous solution to etch and remove the Cu foil through electrochemical reaction and thus a graphene/thermal release tape layered structure was obtained. Thereafter, the graphene was cleaned with deionized water to remove residing etching components. Next, the graphene transferred onto the thermal release tape was contacted with each of PET, a Cu mesh, and a Cu foil, and thereafter, was passed through a transfer roller in the condition that low heat of 90° C. to 120° C. was applied for from 3 to 5 minutes to separate the graphene from the thermal release tape and transfer the graphene onto each of the PET, the Cu mesh, and the Cu foil. FIG. 6 is a graph based on Raman spectroscope analysis of the graphene. From the graph, it is confirmed that a monolayer graphene has been well grown on each of the substrates. If necessary, multilayer graphene may be transferred onto an identical target substrate by repeating the above-described processes on the identical target substrate. With reference to FIG. 8, it is confirmed that tetralayer graphene has been formed on each of the substrates by repeating the above-described processes.

Subsequently, the graphene transferred onto each of the substrates is doped by the roll-to-roll process as shown in FIG. 1. More specifically, AuCl₃—CH₃NO₂ and HNO₃ are used as dopants. The graphene is p-doped by immersing the graphene into the AuCl₃—CH₃NO₂ solution and the solution including 63 wt % HNO₃ for about 5 minutes and passing the graphene through the solutions by using a roll-to-roll transferring apparatus as shown in FIG. 1.

3. Shielding Efficiency Measurement

In order to compare an electromagnetic wave shielding rate depending on whether graphene is provided or not, the shielding efficiency was measured by the electromagnetic wave shielding certificate authority (IST: Intelligent Standard Technology) as follows:

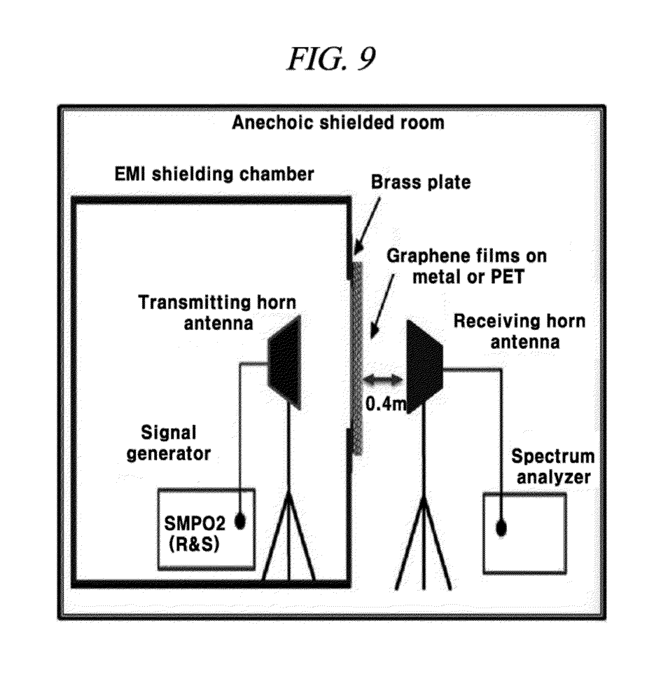

FIG. 9 is a photograph showing an apparatus for measurement of a shielding effect and configuration thereof. More specifically, in the present disclosure, distance between a shielding material and an antenna is maintained 40 cm. For minimization of noise, a shielding box (a mini chamber, 30 cm×25 cm×35 cm) specifically prepared to shield a testing frequency domain to the maximum was used. By generating electromagnetic waves in the shielding box, intensity of the sweeping electromagnetic waves of a general shielding material and a shielding material coated with graphene was measured. For a transmitting horn antenna, a double ridge horn antenna (R&S) is used. For a receiving horn antenna, a double ridge horn antenna (EMCO) was used. For a signal generation device, the SMP02 signal generation device of R&S was used. The device was configured to be inserted into the shielding box and be operated wirelessly therein. For an analysis device, the R3273 spectrum analyzer of ADVANTEST was used. With respect to the frequency domain used for the testing, the high frequency domain of from 2 GHz to 18 GHz was used. Electric field intensity used for each of the frequencies was fixed to 124 dBuV.

The present disclosure has been described in detail with reference to examples. However, it is clear that the present disclosure is not limited to the examples, and may be corrected and modified in various forms by those skilled in the art without departing from the technical concept and the technical area of the present disclosure.

What claimed is:

1. A method for shielding electromagnetic waves by using graphene, the method comprising forming graphene outside or inside an electromagnetic wave generating source to shield electromagnetic waves by the graphene.

2. The method for shielding electromagnetic waves by using graphene of claim 1,
wherein the graphene is formed outside or inside the electromagnetic wave generating source through a chemical vapor deposition method.

3. The method for shielding electromagnetic waves by using graphene of claim 1,
wherein the graphene is formed by transferring the graphene formed on a substrate through a chemical vapor deposition method to the outside or the inside of the electromagnetic wave generating source.

4. The method for shielding electromagnetic waves by using graphene of claim 1,
wherein the graphene is doped.

5. The method for shielding electromagnetic waves by using graphene of claim 1,
wherein sheet resistance of the graphene is 60 Ω/sq or less.

6. The method for shielding electromagnetic waves by using graphene of claim 3,
wherein the substrate includes metal or polymer.

7. A method for shielding electromagnetic waves by using graphene, the method comprising attaching or wrapping a substrate, on which graphene is formed, to or around the outside or the inside of an electromagnetic wave generating source to shield electromagnetic waves by the graphene.

8. The method for shielding electromagnetic waves by using graphene of claim 7,
wherein the graphene is formed on the substrate through a chemical vapor deposition method.

9. The method for shielding electromagnetic waves by using graphene of claim 7,
wherein the graphene is doped.

10. The method for shielding electromagnetic waves by using graphene of claim 7,
wherein sheet resistance of the graphene is 60 Ω/sq or less.

11. The method for shielding electromagnetic waves by using graphene of claim 7,
wherein the substrate includes the form of a foil, a wire, a plate, a tube, or a net.

12. The method for shielding electromagnetic waves by using graphene of claim 7,
wherein the substrate includes metal or polymer.

13. An electromagnetic wave shielding material comprising:
a substrate; and
a graphene formed on the substrate,
wherein the graphene is formed through a chemical vapor deposition method, and has 60 Ω/sq or less of sheet resistance.

14. The electromagnetic wave shielding material of claim 13,
wherein the graphene is doped.

15. The electromagnetic wave shielding material of claim 13,
wherein the substrate includes the form of a foil, a wire, a plate, a tube, or a net.

16. The electromagnetic wave shielding material of claim 13,
wherein the substrate includes metal or polymer.
